(19) United States
(12) Patent Application Publication
(10) Pub. No.: US 2006/0084271 A1
(43) Pub. Date: Apr. 20, 2006

(54) Systems, methods and slurries for chemical mechanical polishing

(76) Inventors: Andy Chunxiao Yang, Shanghai (CN); Chris Chang Yu, Shanghai (CN)

Correspondence Address: TRAN & ASSOCIATES, 6768 MEADOW VISTA CT., SAN JOSE, CA, 95135, US

(21) Appl. No.: 10/970,547

(22) Filed: Oct. 20, 2004

(51) Int. Cl. H01L 21/461; B44C 1/22; C23F 1/00

(52) U.S. Cl. 438/692; 216/88; 438/745

(57) ABSTRACT

Process, slurries formulation and polishing mechanism are disclosed for the formation of silver (Ag) or Ag alloy film features on a substrate using CMP. The process and slurries can achieve Ag or Ag alloy film features with good planarization, low roughness, high reflectivity, and low defectivity.

### BACKGROUND

The invention relates to systems, methods and slurries for polishing silver (Ag) and Ag alloy containing film.

The fabrication of integrated circuits on a semiconductor substrate involves the forming of a multiplicity of layers involving a number of photolithographic processes for each layer. In today's ultra large scale integrated devices, integration density is increasing, and various fine processing techniques have been developed. The process forms patterns in selected areas on the substrate (usually through a deposited insulating layer) for subsequent operations such as inclusion of impurities (ion implantation), oxidation, formation of trenches, and inlaying conductive metals. Each of the metal layers is typically separated from another metal layer by an insulation layer, such as an oxide layer. To enhance the quality of an overlying metal layer, one without discontinuities of other blemishes, the underlying surface for the metal layer should ideally be planar. During the formation of the integrated circuit structures, structures having multiple metallization layers typically require the highest possible conductivity due to the continuing miniaturization of the circuit elements in the structure.

In order to meet the performance criteria of current high end devices and future generations of devices, wirings (conductors) using materials with higher conductivity and better planarization are required. Currently, aluminum alloy is a popular choice as an IC conductor for many IC devices. Copper is being increasingly used as the material for wiring of high performance devices such as microprocessors due to its higher conductivity and superior electro-migration resistance. Ag can also be a wiring material for high speed devices due to its improved conductivity over Cu and Al. Similar to Cu, Ag will also require the use of polishing to form desired patterns.

To meet the needs for larger scale integration, which demands more metal and dielectric layers in devices, the surface topography of the substrate must exhibit exact depth of focus for sub-micron lithography. As discussed in U.S. Pat. No. 6,663,472, chemical mechanical polishing (CMP) is typically used for polishing materials, such as semiconductor substrates and precision optical components, to a high degree of planarity and uniformity. The process is used to initially planarize semiconductor slices and is also used to remove uneven topography created during the forming of the sub-micron circuitry on the substrate. Where the substrate is to be further processed, such as by photolithography and etching, to create integrated circuit structures, any thickness variation in the planarized layer makes it difficult to meet the fine resolution tolerances required to provide high yield of functional die on a substrate. CMP is typically used in planarizing interlayer insulating films and in shallow-trench separation, because it can completely planarize layers to be exposed, reducing the burden on exposure techniques and stabilizing the production yield.

Another application of CMP is to form metal features inlaid in a dielectric layer (in some cases, it is also called damascene), in which CMP is utilized as a method of patterning. In the above mentioned patterning process, trenches are first etched into the dielectric layer, metal layer is next deposited, and finally excess metal is removed using CMP, leaving metal features co-planar with the dielectric layer surface.

A conventional CMP process involves supporting and holding the substrate against a rotating polishing pad that is wet with a polishing slurry and at the same time applying a pressure against the rotating pad. The pH of the polishing slurry controls the chemical reaction, for example, the oxidation of the chemicals that make up the insulating layer of the substrate. The polishing pad is typically made from non-fibrous polyurethane or a polyester-based material. The pad hardness is typically about between 50 and 70 durometers. Polishing pads used with semiconductors are commercially available in a woven polyurethane material. The polishing slurry, which includes an abrasive material, is maintained on the polishing pad to modify the polishing characteristics of the pad in order to enhance the polishing and planarization of the substrate.

The CMP polishing action is typically aided by a slurry which includes for example, small abrasive particles such as colloidal silica (SiO₂) or alumina (Al₂O₃) that abrasively act to remove a portion of the material on the surface being polished. Additionally, the slurry may include chemicals that react with the process surface to assist in removing a portion of the surface material, the slurry typically being separately introduced between the wafer surface and the polishing pad. During the polishing or planarization process, the wafer is typically pressed against a rotating polishing pad. In addition, the wafer may also rotate and oscillate back and forth over the surface of the polishing pad to improve polishing effectiveness.

As discussed in U.S. Pat. No. 6,638,328, typical CMP polishing slurries contain an abrasive material, such as silica or alumina, suspended in an oxidizing, aqueous medium. There are various mechanisms disclosed in the prior art by which metal surfaces can be polished with slurries. The metal surface may be polished using a slurry where a surface film is not formed causing the process to proceed by mechanical removal of metal particles. In using this method, the chemical dissolution rate should be slow in order to avoid wet etching. A more preferred mechanism continuously forms a thin, soft, and abradable layer through a reaction between the metal surface and one or more components in the slurry such as a complexing silverent and/or a film forming layer such as an oxidizer. The thin abradable layer is then removed in a controlled manner by mechanical action. Once the mechanical polishing process has stopped, a thin passive film remains on the surface and controls the wet etching process. Controlling the chemical mechanical polishing process can be easier with this approach.

There are also several different types of slurries used in the CMP process. Common abrasives include silica (SiO₂), alumina (Al₂O₃), ceria (CeO₂), titania (TiO₂), and zirconia (ZrO₂).

### SUMMARY

Methods, systems, and slurries are disclosed for forming Ag interconnects and mirror patterns useful for IC fabrication of circuits including imaging and other device applications. Ag has the highest conductivity and reflectivity compared with other metals, and silver has good anti-electron migration (EM) performance according to its atomic weight. The above properties make silver an ideal candidate for IC fabrication for applications including IC chips (various CPUs and logic chips, ASIC chips, and memory chips such as DRAM, SRAM, EEPROM, and flash memory, among others). Silver can also be used in special devices such as MEMS, MOMS, LCOS, and LPD.

Two kinds of Ag or Ag alloy CMP processes are introduced here according to the manufacturing purpose. One is for Ag or Ag alloy film thinning and planarization and the other is for the Ag or Ag alloy film containing layer surface finishing.

In one embodiment for the first purpose, the process can be realized by using exemplary parameters as follows:
Polishing rate: no less than 2000 A/min.
Down force: no less than 3 psi
Turntable rotation speed: no less than 50 rpm.
Head speed no less than 50 rpm.
Slurry flow rate: from 100-500 ml/min and 150 ml/min is preferred.
Conditioner is needed, in situ or ex situ.
Pad: IC 1000 or 1010 or other Polyurethane or hard pad.

In another exemplary embodiment for the second purpose, the process has following parameters:
Removal rate: no more than 1000 A/min.
Down force: no more than 3 psi
Turntable rotation speed: no more than 50 rpm.
Head speed no more than 50 rpm.
Slurry flow rate: from 100-500 ml/min and 150 ml/min is preferred
Conditioner needed; in situ or ex situ.
Pad: Polytex pad, or other soft pads.
Roughness: equal or below 5 A (after polishing)
Reflectivity above 94% (in visible color range)
Dishing: less than 400 A
Erosion: less than 1000 A.
Defect count: less than 1000.
Ag film loss amount: less than 1000 A.

The system provides a fine surface finishing of silver using CMP and its corresponding slurry formulations to achieve the high reflectivity and planarization of mirror surfaces.

The slurries used for the above processes comprise one of the components or their combination as abrasive, etching silverent, surfactant, complexing silverent, corrosion inhibither, buffer and catalyst.

Five mechanisms are disclosed for applying the Ag or Ag alloy film CMP slurry. They include (1) oxidation-softening-polishing, (2) etching-passivation-polishing, (3) passivation-polishing-etching, (4) self-passivation-etching, and (5) surfactant inhibiting, or any combination thereof.

By optimizing the component in the slurries and CMP process, the Ag or Ag alloy CMP process can be used in IC manufacturing for future generations of IC devices. The above two processes or their combination can be realized with one or more of the following usage and advantages:

Metal silver with a high conductivity and exiting reflectivity performance has promising and important current and future applications in the field of IC, electronic and imaging devices. Such examples include serving as backend interconnects or the mirrors for imaging applications.

Processes and slurries disclosed herein include formation of silver features, high reflectivity of silver or silver alloy mirrors, and fast device speed for the resulting semiconductor devices. For the same solids concentration, the slurries may have a removal rate higher than that achieved using conventional colloidal abrasives yet retains the low defect formation characteristics of conventional colloidal slurry.

The results which can be achieved by CMP include both producing a thinner silver or silver alloy layer compared with the prior layer and producing a metal silver or silver alloy co-planar to dielectric surface. The resulting silver or silver alloy film can have high reflectivity surface, low erosion and dishing, reduced defects, and precise thickness and structure.

The results which can be achieved by CMP include producing a thinner silver or silver alloy layer compared with the prior layer and producing a metal silver or silver alloy co-planar to dielectric surface. In one implementation, the results which can be achieved include a wafer roughness equal or below 5 A (after polishing); a mirror reflectivity of above 95% (in the visible color range); a wafer defect counts less than 1000; a dishing of less than 400 A; and an erosion of less than 1100 A. The silver or silver alloy loss amount is less than 1000 A.

The silver CMP slurry can quickly or finely polish a surface-without making flaws. Further, the CMP abrasive does not contaminate the surface to be polished. Moreover, the CMP slurry and systems and methods disclosed improve the flatness of the polished surface of a substrate.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

The present invention can be more fully understood by reading the subsequent detailed description in conjunction with the examples and references made to the accompanying drawings, wherein:

FIGS. 1A-1H show an exemplary process for polishing a wafer and exemplary structures formed by FIG. 1A.

FIGS. 2A-2C show exemplary cross-sectional views of a wafer during a single damascene process for polishing a wafer with silver formed thereon.

FIGS. 3A-3C show exemplary cross-sectional views of a wafer during a dual damascene process for polishing a wafer with silver formed thereon.

FIGS. 4A-4C show exemplary cross-sectional views of a wafer during a dielectric-fill-in process for polishing a wafer with silver formed thereon.

### DESCRIPTION

There will now be described in detail with reference to the drawings some preferred embodiments of the present invention applied to a chemical mechanical polishing tool for planarizing and forming finely finished surface of Ag or Ag alloy film on semiconductor substrate. In the following description of the preferred embodiments, the same reference numerals as those in the prior figures denote similar parts for convenience of illustration.

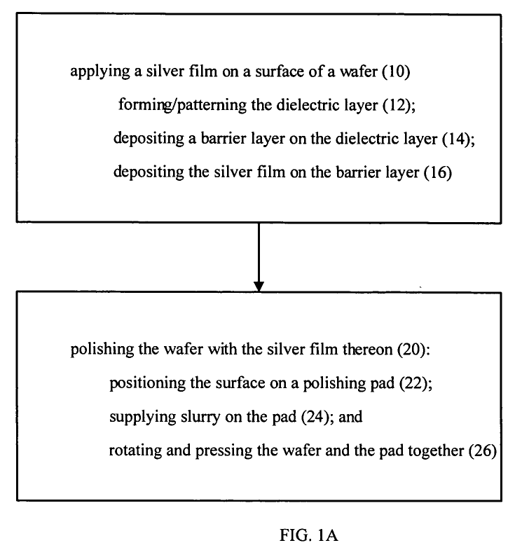

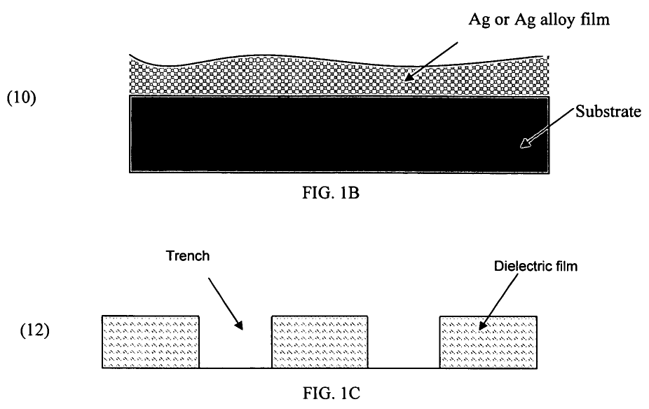

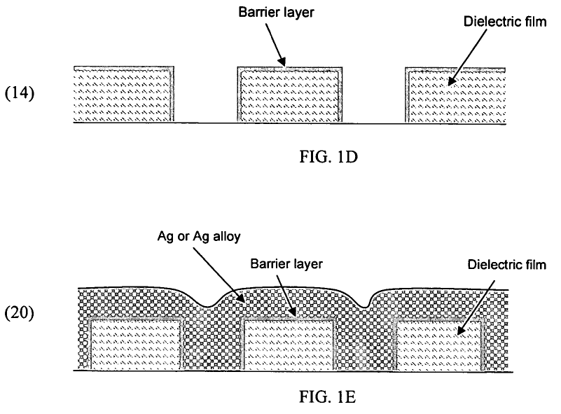

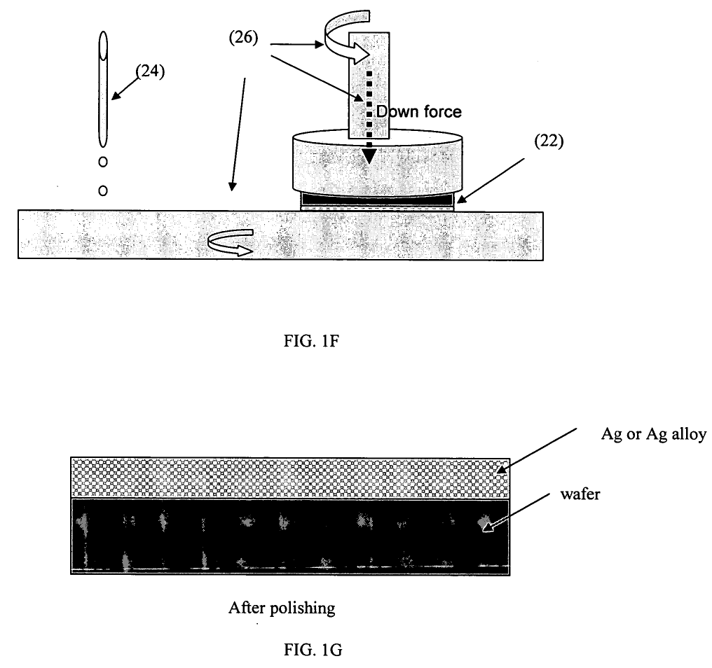

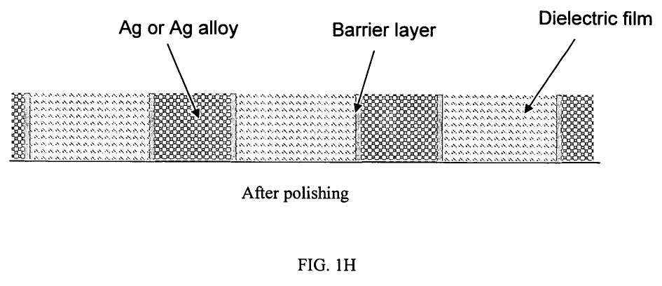

FIG. 1A shows an exemplary process for semiconductor fabrication, while FIGS. 1B-1H show exemplary fabricated structures corresponding to the process of FIG. 1A. The process of FIG. 1A forms a silver (Ag) layer or film on a surface of a wafer (10) and polishes the wafer with the silver layer or film thereon (20).

In one implementation, the formation of the silver film on the wafer surface includes forming/patterning the dielectric layer (12); depositing a barrier layer on the dielectric layer (14); and depositing the silver film on the barrier layer (16).

The polishing of the wafer with the silver film includes positioning the surface on a polishing pad (22); supplying polishing slurry on the pad (24); and rotating and pressing the wafer and the pad at the same time (26). Subsequently, the residue on the wafer can be removed.

The system forms a silver film and polishes the wafer with the silver film. The film can be either pure silver metal or a silver alloy. Since pure silver is a soft metal, it has a tendency to suffer from defects such as scratches. Thus, a silver alloy can be used to harden the metal mirror surface and therefore to reduce or avoid the defect issue. Further, it may improve electro-migration resistance of the film. The silver alloy can be binary or above, which is silver alloyed with Cu, Al, Mg, Ti, Pt, Pd, Ni, Mg, or any other elements. The content of the impurity range from 0.1% to 5%, but in order to keep the high reflectivity performance of silver, the silver metal or alloy should have less than 1% of other metal or impurity.

The slurry can contain an abrasive with SiO₂, Al₂O₃, CaCO₃, ZrO₂, CeO₂, TiO₂ Si₃N₄, AlN, TiN. SiC Al(OH)₃, polymer (for example polyethylene and PTFE), inorganic and organic materials or their combination. The selection of the particle is based on the hardness of passivasion film and the pH value of the slurry. Basically, a softer particle is preferred, for example, polyethylene, PTFE, because silver is a soft metal. The soft particles have a different iso-electric point from the solution pH, and thus the defects such as scratch can be reduced. For applications that require a fast removal rate and hard and thick passivation layer, harder particles such as SiO₂, Al₂O₃, and ZrO₂ can be used.

To disperse the particles and therefore produce a homogeneous slurry solution, surfactants and surfactants assistant agent can be added into the solution. They can be selected from various surfactants which can belong to ion type surfactants, non-ion type surfactants and macromolecular surfactants, among which the non-ion type macromolecular surfactants are preferred, because they are not affected by the pH change of solution. The non-ion type macromolecular surfactant can include but not limited to polyvinylalcohol, polyacrylic acid, polymethyl acrylic acid, acrylic acid-axrylate copolymer, acrylic acid-hydroxypropyl acrylate copolymer, acrylic acrylate copolymer copolymer of maleic acid and acrylic acid, acrylic acid-hydroxypropyl acrylate ternary polymer, BOF, polyvinyl alcohol modified by copolymerization, copolymer of alkanolalkyl methacrylate with alkanolamine, maleic-styrene copolymer and polyethylene glycol mono methyl copolymer, carboxylic acid modified polyvinylalcohol, derivative of copolymer of ethylene glycol and polyamine, specific copolymer dispersant, hydroxy propyl acrylate and any other copolymer of monomers, isobutene, propylene oxide, 2-hydroxyethyl, methyl acrylate, maleic anhydride, acrylic acid, methacrylic acid acrylamide methyl acrylamide styrene, vinyl pyridine ketone, among others.

As to the complex silverent, silver is a soft and gummy metal and its ion can be sensitive to chemical or physical factors. Many chemical or physical factors, such as impurity, S²⁻ and Cu, for example, react Ag⁺ into silver or other deposited compounds. These compounds can leave significant amounts of polishing residue. These compounds can also render the pad dirty and make the wafer fabrication process unstable and defect prone. To avoid this case, a complex silverent of Ag⁺ is introduced. The complex silverent can be selected from a group including NH₄⁺, X(X=Cl⁻, Br⁻ I⁻), EDTA, CyDTA, DTPA, EDTP, EGTA, HEDTA, NTA, Tetren, and Trien, among others.

The CMP system can have a fixed slurry delivery system or can have a computer controlled slurry delivery system. The computer controlled slurry flow system decides the optimal flow rate of the slurry and the optimal distance between a slurry injector and a polish head in order to get the maximum value of the removal rate of the CMP process. The slurry flow system controls the flow rate of the slurry that is dispersed on a polish pad and the distance between a slurry injector and a polish head to optimize the flow of the slurry on the polish pad. The rotation rate of the polish pad and the polish head, the pressure on the polish head and the pressure on the wafer under the polish head are controlled for maintaining the process parameters of a CMP process. In one implementation, the system includes a current detector that senses a motor current for driving a turntable of the CMP system and the turn table is adapted for rotating the polish pad of the CMP system. The system changes the flow rate of the slurry and the position of the slurry injector, thus changing the distance between the injector and the polish head, until the current reaches a minimum value.

In one embodiment, the polishing of the wafer includes forming a dielectric layer on a semiconductor substrate; patterning the dielectric layer; lining (depositing) trenches and vias with a barrier material; and then filling the trenches/vias with metal silver or silver alloy into the trenches and vias. CMP is then applied to the silver or silver alloy film.

The dielectric layer can be selected from HDP, PETEOS, SRO, BPSG, FSG, low k materials and any other oxides and dielectric materials. Further, the dielectric layer can be formed using the methods of CVD, PVD, Spin-on or any other suitable method. The dielectric layer's patterns can be realized by using the dry etch or wet etch method. The formation of the film of metal silver or silver alloy layer can be done using electro-plating, chemical plating, CVD or PVD, among others.

The CMP process applied onto the silver or silver alloy is realized as following: positioning the silver or silver alloy surface of a wafer onto a polishing pad; supplying the CMP slurry onto the polishing pad; rotating the wafer and the polishing pad with certain speeds, respectively; At the same time, press the wafer towards the pad with a certain down force. During or after the polishing, the pad condition is applied to remove the polishing residue. In addition, the polished wafer is cleaned in a desired cleaning solution to remove polishing residue.

The materials polished include silver or silver alloy, barrier layer, and dielectric layer. Moreover, the polishing rate between the silver or silver alloy, barrier layer and the dielectric layer can be either the same or different, according to the details of the fabrication process. The slurries used for the CMP process can contain abrasive, surfactant, oxidant, complexant, corrosion inhibitor, buffer and catalyst.

In one embodiment, the CMP process uses the following parameters: CMP head down force is no less than 3 psi; turntable rotation speed is no less than 50 rpm; head rotation speed is no less than 50 rpm.; slurry flow rate is from 100-500 ml/min and 150 ml/min is preferred. The silver or silver alloy polishing rate is no less than 2000 A/min. The CMP pad can be selected from IC 1000, IC 1010 or other Polyurethane or hard pad. In another embodiment, a process for polishing a layer includes providing an silver or silver alloy containing surface; positioning this silver or silver alloy containing surface onto a polishing pad; applying the rotation and press to the silver or silver alloy containing surface and the pad. At the same time, CMP slurry is supplied to the pad, and pad conditioning is applied to remove the polishing residue during or after or both during and after the polishing process.

The film of silver or silver alloy containing surface can be on the semiconductor substrate, dielectric substrate, glass substrate or any other material substrates. Silver alloy can be used instead of silver to overcome the small hardness of pure silver. The silver alloy can be binary or above, which is silver alloyed with Cu, Al, Mg, Ti, Pt, Pd, Ni, or any other elements. The silver or silver alloy containing surface can be either a whole silver or silver alloy surface or a partially containing silver or silver alloy surface, for example, a silver or silver alloy co-planar to dielectric surface. The contents of impurity in the silver alloy can be from 0.1% to 5%. In applications that need the high reflectivity performance of Ag, less than 1% containing quantity of other metal should be present.

The dielectric layer can be HDP, PETEOS, SRO, BPSG, FSG, low k materials and any other oxides and dielectric materials, which can be formed using the methods of CVD, PVD, Spin-on or any other suitable methods.

The film of silver or silver alloy containing surface can be formed using damascene or dual damascene methods. The damascene or dual damascene method includes forming a dielectric layer on a substrate; patterning the dielectric layer; lining the trench and via with the barrier material; then filling the metal silver or silver alloy into the trench and via; then through polishing or etch or their combination, the film of silver or silver alloy containing surface is formed.

Another method for producing silver or silver alloy containing surface is a dielectric filling in method that includes: forming a silver or silver alloy layer on a substrate; patterning the silver or alloys layer; optionally lining the trench and via with barrier material; then filling the dielectric material. Then through etch or CMP or their combination, the film or surface containing silver or silver alloy is formed, with silver or silver alloy surface co-planar with dielectric layer. Other methods of producing silver or silver alloy film can be used as well. For example, the silver film can be made using the lift off method.

In one exemplary CMP process for the above mentioned integration method, the CMP head down force is no more than 3 psi; turntable rotation speed is no more than 50 rpm; head rotation speed is no more than 50 rpm.; slurry flow rate is from 100-500 ml/min and 150 ml/min is preferred, and the silver or silver alloy polishing rate is no more than 1000 A/min. The polishing pad can be polytex pad or other soft pads, and conditioning of the pad (in situ or ex situ) is needed.

The slurry for polishing silver or silver alloy contains abrasive, etching agent, surfactants, complexing agent, inhibiter, and buffer. The polishing mechanism with the slurry can be oxidation-softening-polishing mechanism, etching-passivation-polishing mechanism, passivation-polishing-etching mechanism, self-passivation-etching mechanism and surfactant inhibiting mechanism, or their combination. The abrasive can be selected from but not limited to SiO₂, Al₂O₃, CaCO₃, ZrO, CeO₂, TiO₂ Si₃N₄, AlN, TiN. SiC Al(OH)₃, MgO, polymer (for example polyethylene and PTFE), inorganic and organic materials or their combination. The selection of the particle is based on the hardness of passivasion film and the pH value of the slurry. Basically, softer particle is preferred. Examples include polyethylene and PTFE, because silver is a soft film and has a different iso-electric point from the solution pH, and thus causing few defects. In cases that require a high removal rate and hard and thick passivation layer, a slightly harder particle such as SiO₂, Al₂O₃, and CeO₂ can be used.

The pH value of slurries can be from −2 to 16, because in solutions free from nitric acid or complexing substance (ammonia, cyanides etc.) silver strongly resists corrosion. For Oxidation-Softening-Polishing Mechanism, the pH value is preferred from 6 to 16, while for Etching-Passivation-Polishing Mechanism, Passivation-polishing-etching mechanism, −2 to 8 pH value is preferred. For Self-passivation-etching mechanism, 5-10 pH value is preferred. For surfactant inhibiting mechanism, the whole range of pH can be applied. Although a wide range of pH value can be used, pH value from 8-11 is preferred.

The surfactant can be selected from but not limited to polyvinylalcohol, polyacrylic acid, polymethyl acrylic acid, acrylic acid-axrylate copolymer, acrylic acid-hydroxypropyl acrylate copolymer, acrylic acrylate copolymer copolymer of maleic acid and acrylic acid, acrylic acid-hydroxypropyl acrylate ternary polymer, BOF, polyvinyl alcohol modified by copolymerization, copolymer of alkanolalkyl methacrylate with alkanolamine, maleic-styrene copolymer and polyethylene glycol mono methyl copolymer, carboxylic acid modified polyvinylalcohol, derivative of copolymer of ethylene glycol and polyamine, specific copolymer dispersant, hydroxy propyl acrylate and any other copolymer of monomers, isobutene, propylene oxide, 2-hydroxyethyl, methyl acrylate, maleic anhydride, acrylic acid, methacrylic acid acrylamide methyl acrylamide styrene, vinyl pyridine ketone or their combination.

The complexing agent can be selected from but not limited to NH₄⁺, X(X=Cl⁻, Br⁻ I⁻), EDTA, CyDTA, DTPA, EDTP, EGTA, HEDTA, NTA, Tetren, and Trien, or their combination. The buffer can be organic compounds such as, ethylenediamine, oxalic acid, or inorganic compounds such as HNO₃, NH₃.H₂O. The inhibitor can be an organic surfactant or compound containing element N, or S, or O, or P, or Zn, or π bond such as 1,2,3-benzotriazole, BTA, Indene, Benzofuran(coumarone), thionaphthene, 1-benzazole,4-isobenzazole, indolenine or pseudoisoindole, isoindazole, indazole, benzimidazole, indiazole, 1-pyrido[2,3-d]-υ-triazole, 1-pyrazolo pyrazine,2-υ-triazolo[b]pyrazine, 1,2-benzeisoxazole.benzopseudoxazole, benzofurazan, purine or their combination.

The etch agents are selected from but not limited to HNO₃, HX(X=Cl, Br, I), HXO₃ (X=Cl, Br, I). I⁻+I₂, Cl⁻+Cl₂, Br⁻+Br₂, AgNO₃, or their combination.

The oxidizer can be H₂O₂, salt of S₂O₄²⁻ or S₂O₈²⁻, KIO₃, KMnO₄, KNO₃ HNO₃, bromate, Bromine, Butadiene, Chlorates, Chloric acid, Chlorine, Chlorites, Chromates, Chromic Acid, Dichromates, Fluorine, haloates, Halogens, hypochlorites, Nitrous oxide, Ozanates, oxides, oxygen, oxygen difluoride ozone, peracetic acid perborates, perhaloate, percarbonates, perchlorates, perchloric acid, perhydrates, peroxides, persulfates, permanganates, sodium borate sulfuric acid, or their combination.

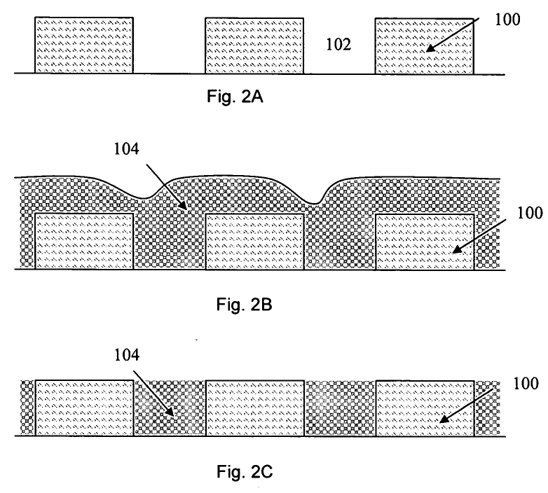

Various CMP implementations of the above process are discussed next. FIGS. 2A-2C show an exemplary process for forming a silver film pattern using a damascene process. The wafer or substrate material can be selected from HDP, PETEOS, TEOS, SRO, BPSG, FSG, low k material and any other oxides and dielectric materials. Trench patterns 102 are formed, typically using a dry etch method, but wet etch can be used as well. A dielectric layer 100 is formed on the substrate and suitably etched. After etching the dielectric layer 100 and before silver deposition, a barrier (not shown) such as a diffusion barrier is formed to prevent the silver's diffusion. Next, a layer of silver 104 is deposited using a number of suitable methods including electro-plating, electroless-plating, chemical plating, CVD and PVD, among others. A polishing operation is then performed to remove silver or silver alloy from above the dielectric layer surface and provide a flattened surface suitable for semiconductor operations. The polishing operation can be CMP and can include positioning the surface on a polishing pad; supplying a polishing slurry on the pad; and rotating and pressing the wafer and the pad together. Subsequently, residue on the wafer can be removed.

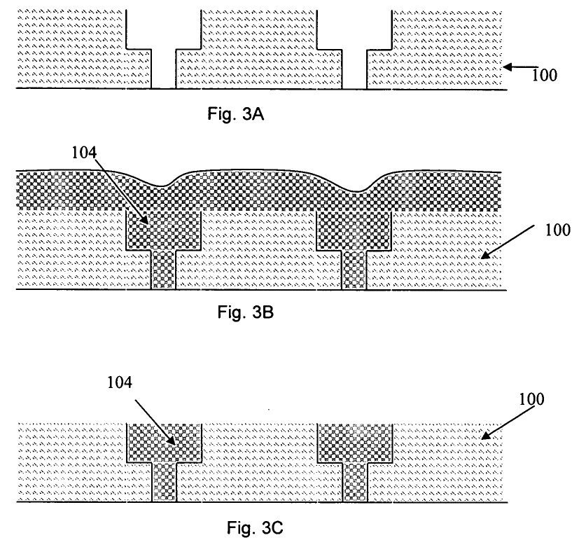

FIGS. 3A-3C shows a dual damascene process in which silver layer 104 or film above the substrate is removed using a CMP process, leaving silver co-planar with the substrate. The CMP process has the following exemplary process ranges:
Polishing rate: no less than 2000 A/min.
Head down force: no less than 3 psi
Turntable rotation speed: no less than 50 rpm.
Head speed no less than 50 rpm.
Slurry flow rate: from 100-500 ml/min and 150 ml/min is preferred.
Conditioner in situ or ex situ.
Pad IC 1000 or 1010 or other Polyurethane or hard pad.

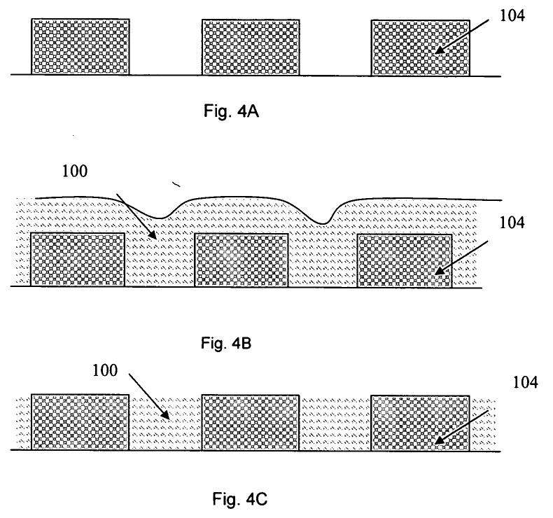

In some applications, a smooth, planar and highly reflective surface is required. For these applications, the structure of FIG. 2C and FIG. 3C may need additional processing such as a silver fine surface finishing operation. Also the structure of FIG. 2C can be obtained through the oxide fill in method shown in FIGS. 4A-4C. This silver CMP process for the surface finishing is different from the forgoing silver CMP process. In the previous silver CMP, the removal rate should be greater than 2000 A/min. However, in this CMP process, the goal is to enhance silver surface reflectivity, smoothness and planarization and the amount of silver removed is not the focus. Therefore, the removal rate should be no more than 1000 A/minute, and only a small amount of silver film needs to be removed from the surface. This CMP process basically has a number of benefits. One is that the process minimizes dishing and erosion effects. Since the silver films, dielectric over the silver, and dielectric layer between inlaid silver features are both removed softly and slowly, and with a small amount, the process provides better dishing and erosion characteristics than a process that uses a fast but rough polish. Other benefits include improved silver film surface flatness, enhanced reflectivity, and reduced defects on the silver surface.

One exemplary silver fine surface finishing CMP process conforms to the following characteristics:
Removal rate: no more than 1000 A/min.
Down force: no more than 3 psi
Turntable rotation speed: no more than 50 rpm.
Head speed no more than 50 rpm.
Slurry flow rate: 100-500 ml/min;
   150 ml/min is preferred
Conditioner needed; in situ or ex situ.
Pad: Polytex pad, or other soft pads.
Roughness: equal or below 5 A (after polishing)
Reflectivity above 95%. (in visible color range)
Dishing: less than 400 A
Erosion: less than 1000 A.
Defect count: less than 1000.
Ag film loss amount: less than 1000 A.

The following silver CMP mechanisms can be used:

a. Oxidation-Softening-Polishing Mechanism.

In this mechanism, the silver film is oxidized quickly into AgO or Ag₂O or Ag₂O₂ and an oxidation layer is formed on the silver film surface. The oxidation silverent can be H₂O₂, salt of S₂O₄²⁻ or S₂O₈²⁻, KIO₃, KMnO₄, KNO₃ HNO₃, bromate, Bromine, Butadiene, Chlorates, Chloric acid, Chlorine, Chlorites, Chromates, Chromic Acid, Dichromates, Fluorine, haloates, Halogens, hypochlorites, Nitrous oxide, Ozanates, oxides, oxygen, oxygen difluoride ozone, peracetic acid perborates, perhaloate, percarbonates, perchlorates, perchloric acid, perhydrates, peroxides, persulfates, permanganates, sodium borate sulfinuric acid, for example or their combination. The oxidation film can be harder or softer than the silver metal film, and can have a certain thickness. The oxidation film isolates silver film from contacting with the solution, and it is in direct contact with the solution. Therefore at the interface between the oxidization layer and the solution, the top atom of oxidization will have a weak connection with its under atoms due to physical and chemical factors, for example, the hydrogen force, surfactants or ultrasonic force. A polishing is implemented to remove the weak-linked portion of the oxidization layer surface, and with the polishing is going on the oxidation of Ag film and surface's weak linked function are also be proceeded under certain chemical circumstance. Thus the removal and planarization of Ag film is realized. The polishing parameters and abrasive's hardness and size should be selected in terms of the oxidization layer's hardness, density, and thickness. For passivation film with lower density, and softer and thinner characteristics, a gentler set of process parameter should be selected, such as low rotation, low down force, and a slurry with softer and smaller abrasives.

b. Etching-Passivation-Polishing Mechanism

In this mechanism the silver film firstly dissolved into solution as Ag⁺ ion or other ion form. This can be realized by using HNO₃ or other chemical in the slurry. But in the solution there still exist other chemicals or ions such as Cl⁻, I⁻, Br⁺ CH₃COO, C₆H₅O₈³⁺, PO₄³⁻, C₂O₄²⁻, S²⁻, C₆H₄(OH)COO⁻, etc, which can react with silver⁺ or other silver ion form and result in to a silver precipitation compound, such as, AgCl, AgI, AgBr, CH₃COOAg, Ag₃C₆H₅O₈, Ag₃PO₄, Ag₂C₂O₄, silver₂S, C₆H₄(OH)COOAg, among others. The precipitation compound is deposited on the surface of silver film to form a passivation layer and thus inhibits the continuous silver's dissolution into solution. However, when the surface is polished, the precipitation compound layer will be destroyed and then the silver film's dissolution will proceed again. Through this repeated process of silver film's etching, silver ion's precipitation, and mechanical polishing, a system balance can be produced and the silver film's thinning and planarization can be realized.

c. Passivation-Polishing-Etching Mechanism

This mechanism is also mainly achieved through the above three factors. The first step is, passivation layer's growth on silver film surface. The passivation layer, maybe hard or soft, not like the mechanism (b), the passivation layer is in stead of coming from the precipitation growing directly form the silver film surface. So the passivation layer's property may be much different from that of mechanism (b). The passivating silverent can be seelected from a group consisting HCl, HI, HBr, CH₃COOH, H₃C₆H₅O₈, H₃PO₄, H₂C₂O₄, H₂S, C₆H₄(OH)COOH or other. Next, when the polishing is carried out, the passivation layer can be removed. Subsequently, silver etch silverent in the solution will play its role to reduce the silver film's thickness. The etch silverent can be HNO₃, AgNO₃ or other chemical. Thus, a passivation, polishing, and etching system similar to the above Etching-Passivation-Polishing mechanism is formed, and the thinning and planarization of silver film can be realized.

d. Self-Passivation-Etching Mechanism

As it is known, two reactions with silver are as follows:
Ag+HClO₃→AgCl (precipitation)+AgClO₃+3H₂O
AgClO₃+2NH₃→Ag(NH₃)₂ClO₃
AgCl+2NH₃+Ag(NH₃)₂Cl (1)
Formula (1) is also suitable for HBrO₃ and HIO₃
Ag+HCl→AgCl (precipitation); AgCl+HCl→AgCl₃²⁻+2H⁺ (2)

Formula (2) is also suitable for HBr and HI.

Formulas (1) and (2) show that in the solution there exist at the same time the etching and passivation activities. When the NH₃ or X⁻(X=Cl, Br, I) quantity in the slurry are properly prepared, a passivation dominating reaction will be obtained. Then at the aid of polishing, under-controlled silver film planarization and thickness reduction can be realized

e. Surfactant Inhibiting Mechanism

In this mechanism the inhibiter are used as the passivation layer to prevent the silver film's etching. But under the mechanical influence of polishing, the silver film surface will be exposed to the etch silverent in the solution partially or completely, which results in etching of silver surface. Meanwhile, surfactant still attempts to adsorb on the silver film. As a result, a balance between sorption and desorption of surfactant will be reached. This also makes a controlled silver film planarization and thickness reduction process.

The etch silverent in this mechanism can be any of those in forgoing mechanisms. And the inhibitor can be selected from a group consisting of some organic surfactants or compounds containing element N, or S, or O, or P, or Zn, or π bond such as 1,2,3-benzotriazole, BTA, Indene,Benzofuran(coumarone), thionaphthene, 1-benzazole, 4-isobenzazole, indolenine or pseudoisoindole, isoindazole,indazole, benzimidazole, indiazole, 1-pyrido[2,3-d]-1-triazole, 1-pyrazolo pyrazine,2-υ-triazolo[b]pyrazine, 1,2-benzeisoxazole.benzopseudoxazole, benzofurazan, and purine, among others.

The pH value of slurry can be from −2 to 16, because in solutions free from nitric acid or complexing substance (ammonia, cyanides etc.) silver strongly resists corrosion. Thus, for mechanism a, the pH value is preferred from 6 to 16, while for mechanism b and c, −2 to 8 pH value is preferred. For mechanism d, 5 to 10 pH value is preferred. For the mechanism e, the whole range of pH can be applied.

While the invention has been described by way of example and in terms of the above, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A process for semiconductor fabrication, comprising:
forming a silver film on a surface of a substrate; and
polishing or etching the silver film on the surface of the-substrate.

2. The process of claim 1, comprising:
positioning the surface proximal to a polishing pad;
supplying slurry to the pad; and
rotating and pressing the wafer and the pad together.

3. The process of claim 2, wherein the polishing comprises one mechanism of:
Oxidation-Softening-Polishing, Etching-Passivation-Polishing, Passivation-polishing-etching, Self-passivation-etching and Surfactant inhibiting.

4. The process of claim 2, wherein the slurry includes an abrasive comprising one or combination of: SiO₂, Al₂O₃, CaCO₃, ZrO, CeO₂, TiO₂ Si₃N₄, AlN, TiN. SiC Al(OH)₃, polyethylene and PTFE.

5. The process of claim 2, wherein the slurry includes a surfactant comprising one or combination of: polyvinylalcohol, polyacrylic acid, polymethyl acrylic acid, acrylic acid-axrylate copolymer, acrylic acid-hydroxypropyl acrylate copolymer, acrylic acrylate copolymer copolymer of maleic acid and acrylic acid, acrylic acid-hydroxypropyl acrylate ternary polymer, BOF, polyvinyl alcohol modified by copolymerization, copolymer of alkanolalkyl methacrylate with alkanolamine, maleic-styrene copolymer and polyethylene glycol mono methyl copolymer, carboxylic acid modified polyvinylalcohol, derivative of copolymer of ethylene glycol and polyamine, specific copolymer dispersant, hydroxy propyl acrylate and any other copolymer of monomers, isobutene, propylene oxide, 2-hydroxyethyl, methyl acrylate, maleic anhydride, acrylic acid, methacrylic acid acrylamide methyl acrylamide styrene, and vinyl pyridine ketone.

6. The process of claim 2, wherein the the pH value of the slurry is between −2 and 16.

7. The process of claim 2, wherein the slurry includes: an abrasive, an etching silverent, one or more surfactants, a complexing silverent, an corrosion inhibiter, a catalyst and a buffer.

8. The process of claim 7, wherein the complexing silverent comprises one of: NH₄⁺, X(X=Cl⁻, Br⁻ I⁻), EDTA, CyDTA, DTPA, EDTP, EGTA, HEDTA, NTA, Tetren, and Trien.

9. The process of claim 7, wherein the buffer is organic compounds such as, ethylenediamine, oxalic acid, or inorganic compounds such as HNO₃, NH₃.H₂O.

10. The process of claim 7, wherein the inhibitor is an organic surfactant or compound containing one of element N, or S, or O, or P, or Zn., and a π-bond.

11. The process of claim 7, wherein the inhibitor is an organic surfactant or compound comprising one of: 1,2,3-benzotriazole, BTA, Indene, Benzofuran(coumarone), thionaphthene, 1-benzazole,4-isobenzazole, indolenine or pseudoisoindole, isoindazole,indazole, benzimidazole, indiazole, 1-pyrido[2,3-d]-υ-triazole, 1-pyrazolo pyrazine,2-α-triazolo[b]pyrazine, 1,2-benzeisoxaole.benzopseudoxazole, benzofurazan, purine and their combination.

12. The process of claim 7, wherein the etch silverent comprises one of: of HNO₃, Ag NO₃, HX(X=Cl, Br, I), HXO₃ (X=Cl, Br, I).I⁻+I₂, Cl⁻+Cl₂, Br⁻+Br₂.

13. The process of claim 7, wherein the oxidizer comprises one of: H₂O₂, salt of S₂O₄²⁻ or S₂O₈²⁻, KIO₃, KMnO₄, KNO₃ HNO₃, bromate, Bromine, Butadiene, Chlorates, Chloric acid, Chlorine, Chlorites, Chromates, Chromic Acid, Dichromates, Fluorine, haloates, Halogens, hypochlorites, Nitrous oxide, Ozanates, oxides, oxygen, oxygen difluoride ozone, peracetic acid perborates, perhaloate, percarbonates, perchlorates, perchloric acid, perhydrates, peroxides, persulfates, permanganates, sodium borate sulfuric acid.

14. The process of claim 2, comprising applying pad conditioning to condition the pad and remove polishing residue before and/or during and/or after wafer polishing.

15. The process of claim 1, wherein the forming and patterning of the silver film comprises applying a damascene method or a dual damascene method.

16. The process of claim 15, comprising:
forming a dielectric layer on a substrate;
patterning the dielectric layer with trenches and vias etched into the said dielectric layer;
depositing a barrier material into the trench or via;
filling the trench or via with the silver film;
removing and planarizing silver material above the dielectric substrate using CMP, and
leaving silver in the said trench and via co-planar with the dielectric substrate.

17. The process of claim 16, comprising fabricating devices with improved device speed and performance.

18. The process of claim 16, comprising fabricating at least one of: logic devices, ASIC devices, DRAM, SRAM, Flash, EEPROM, FeDRAM, MRAM, MEMS, LCOS and MOMS devices.

19. The process of claim 1, wherein the silver film comprises one of: silver, a silver metal and a silver alloy.

20. The process of claim 1, comprising:
forming a dielectric layer on the wafer;
patterning the dielectric layer;
depositing a barrier layer on the dielectric layer; and
depositing the silver film on the barrier layer.

21. The process of claim 20 wherein the barrier layer is deposited on a trench or a via.

22. The process of claim 20 wherein the dielectric layer comprises one of: HDP, PETEOS, TEOS, SRO, BPSG, PSG, FSG, and Si₃N₄.

23. The process of claim 20 wherein the dielectric layer comprises a low k material.

24. The process of claim 20 wherein the dielectric layer is formed using one or more of:
CVD, PVD and spin-on.

25. The process of claim 20 wherein patterning the dielectric layer comprises dry etching or wet etching the dielectric layer.

26. The process of claim 1, comprising forming a semiconductor structure containing Ag or Ag alloy film using one of: electroplating, electroless-plating, chemical plating, chemical vapor depositing (CVD) and physical vapor depositing (PVD).

27. The process of claim 1, wherein polishing the silver film comprises:
positioning the wafer proximal to a polishing pad;
providing slurry on the polishing pad;
rotating the wafer and the polishing pad; pressing the wafer to the pad; and
removing a polishing residue from the wafer.

28. The process of claim 27, comprising conditioning the pad before or during or after the polishing.

29. The process of claim 27, wherein the slurry comprises one or more of: an abrasive, a surfactant, an oxidant, a complexant, a corrosion inhibitor, a pH buffer and a catalyst.

30. The process of claim 27, wherein a CMP head down force is at least 3 psi, a turntable rotation speed is at least 50 rpm, a head rotation speed is at least 50 rpm, a slurry flow rate is between 100 and 500 ml/min, a slurry flow rate is 150 ml/min, and a silver film polishing rate is at least 2000 A/min.

31. The process of claim 27, wherein the pad comprises one of: an IC 1000 pad, an IC 1010 pad, a polyurethane pad and a hard pad.

32. The process of claim 27, wherein the silver film comprises between 0.1% and 5% in impurity.

33. The process of claim 27, wherein the silver film includes that co-planar with a surface of the dielectric layer.

34. The process of claim 27, comprising polishing one of: the silver film, the barrier layer, and the dielectric layer.

35. The process of claim 27, wherein the silver film, the barrier layer and the dielectric layer is polished at one or more polishing rates.

36. The process of claim 1, comprising filling the wafer with a dielectric material.

37. The method of claim 36, wherein the dielectric material filling comprises:
patterning the silver film to form a trench;
patterning the silver and forming barrier film;
filling the trench with the dielectric material;
planarizing dielectric layer using CMP or etch back;
removing dielectric layer above the silver surface; and
using a fine finish CMP process to remove silver and dielectric residue from silver surface and improving reflectivity and planarization of the silver surface.

38. The process of claim 37, wherein the polishing provides a surface having a roughness equal or below 7 A; a reflectivity of at least 94%; a defect count of less than 1000; a dishing of less than 400 A; and an erosion of less than 1000 A.

39. The process of claim 37, comprising polising with a soft pad, wherein the polishing pad is a polytex pad.

40. The process of claim 1, wherein the silver film comprises a silver alloy with silver and one of Cu, Al, Mg, Ti, Pt, Pd, and Ni.

41. The process of claim 37, wherein a CMP head down force is no more than 3 psi; a turntable rotation speed is no more than 50 rpm; a head rotation speed is no more than 50 rpm; a slurry flow rate is between 100 and 500 ml/min; a slurry flow rate is 150 ml/min a silver film polishing rate no more than 1000 A/min; and wherein the pad is one of a polytex pad and soft pad.

42. The process of claim 37, comprising fabricating one of the following: an imaging device, a laser component, and an optical device requiring high reflectivity and planarization.

43. The process of claim 37, comprising fabricating mirrors made of silver or silver alloy with enhanced optical reflectivity, improved imaging contrast, and improved local and global optical signal uniformity.
